(19) United States
(12) Patent Application Publication
(10) Pub. No.: US 2026/0255802 A1
(43) Pub. Date: Aug. 27, 2026

(54) LIGHT EMITTING DEVICE AND METHOD OF MANUFACTURING THE SAME

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); KUO-CHENG HSU, TAICHUNG CITY (TW); KER TAI CHU, TAIPEI CITY (TW)

(21) Appl. No.: 19/546,461

(22) Filed: Feb. 23, 2026

(30) Foreign Application Priority Data
Feb. 24, 2025 (CN) 202510206724.X
Jan. 8, 2026 (CN) 202610024291.0

(51) Int. Cl. H10K 59/121; H10D 30/01; H10D 30/67; H10K 59/12

(52) U.S. Cl. CPC H10K 59/1213; H10D 30/0314; H10D 30/6725; H10D 30/6731; H10K 59/1201

(57) ABSTRACT

A method of manufacturing a light emitting device includes providing a substrate; forming a buffer material over the substrate; performing a planarization process on the buffer material to produce a buffer layer, the buffer layer having a flat upper surface; forming a circuit tier over the buffer layer, the circuit tier including a transistor; and forming a light emitting pixel over the circuit tier, and the light emitting pixel including a light emitting material. Wherein forming the transistor includes: forming an active layer over the buffer layer; forming a gate over the active layer; forming source/drain regions on portions of the active layer on opposite sides of the gate, and forming a channel below the gate and between the source/drain regions.

### PRIORITY CLAIM AND CROSS-REFERENCE

This application claims the benefit of China Patent Application Serial No. 202510206724.X, filed on February 24, 2025, and claims priority to China Patent Application Serial No. 202610024291.0, filed on January 08, 2026, the entirety of which are incorporated by reference herein.

### BACKGROUND OF THE DISCLOSURE

### FIELD OF THE DISCLOSURE

The present disclosure relates to a light emitting device, and more particularly to an organic light emitting device and a method of manufacturing the same.

### DESCRIPTION OF THE PRIOR ART

Organic light emitting displays (OLEDs) are widely used in most high-end electronic devices. However, due to limitations in current technology, pixel definition requires to be achieved by applying a light emitting material onto a substrate with a mask, but in many cases, the critical size of the mask cannot be smaller than 100 micrometers. Therefore, achieving a pixel density of 800 ppi (pixels per inch) or higher has become a challenge for display manufacturers.

### SUMMARY OF THE DISCLOSURE

To address the technical problems existing in the current technology, the present disclosure proposes a method of manufacturing a light emitting device, comprising: providing a substrate; forming a buffer material over the substrate; performing a planarization process on the buffer material to produce a buffer layer, the buffer layer having a flat upper surface; forming a circuit tier over the buffer layer, the circuit tier including a transistor; and forming a light emitting pixel over the circuit tier, and the light emitting pixel including a light emitting material. Wherein forming the transistor comprises: forming an active layer over the buffer layer; forming a gate over the active layer; forming source/drain regions on portions of the active layer on opposite sides of the gate, and forming a channel below the gate and between the source/drain regions.

In some embodiments, a chemical mechanical polishing (CMP) process is performed on the buffer material to planarize a surface of the buffer material. In some embodiments, a cleaning process is performed on the buffer material after the chemical mechanical polishing process. In some embodiments, forming the active layer over the buffer layer comprises: forming an active material over the buffer layer; performing a planarization process on the active material; and performing a patterning process on the active material to produce the active layer. In some embodiments, the planarization process comprises a chemical mechanical polishing process, and the method further comprises performing a cleaning process on the active material after the chemical mechanical polishing process. In some embodiments, forming the gate over the active layer comprises: forming a gate material layer over the active layer; performing a planarization process on the gate material layer; and performing a patterning process on the gate material layer to produce the gate. In some embodiments, the planarization process comprises a chemical mechanical polishing process, and the method further comprises performing a cleaning process on the gate material layer after the chemical mechanical polishing process.

The present disclosure proposes a method of manufacturing a light emitting device, comprising: forming a circuit tier on a substrate, the circuit tier comprising a transistor; and forming a light emitting pixel over the circuit tier, and the light emitting pixel comprising a light emitting material. Wherein the substrate comprises a base material and a buffer layer over the base material. Forming the transistor comprises: forming an active layer over the buffer layer; forming a gate over the active layer; forming source/drain regions on portions of the active layer on opposite sides of the gate, and forming a channel between the source/drain regions, wherein the active layer is produced with a flat upper surface through a planarization process.

In some embodiments, the buffer layer provides an upper surface of the substrate, and the method further comprises performing a chemical mechanical polishing (CMP) process on the buffer layer to planarize the upper surface of the substrate. In some embodiments, the active layer is produced with a flat upper surface through a chemical mechanical polishing (CMP) process. In some embodiments, a gate dielectric layer is further comprised between the channel and the gate, and the method further comprises performing a planarization process on the gate dielectric material to form the gate dielectric layer. In some embodiments, the method further comprises performing a planarization process, such as a chemical mechanical polishing (CMP) process, on the gate to produce a flat upper surface.

The present disclosure proposes a light emitting device, comprising: a substrate comprising a base material and a buffer layer over the base material; a circuit tier on the substrate, the circuit tier comprising a transistor; and a light emitting pixel over the circuit tier, and the light emitting pixel comprising a light emitting material. The transistor comprising: an active layer over the buffer layer; a gate over the active layer; and source/drain regions located at the active layer and on opposite sides of the gate, with a channel below the gate and between the source/drain regions, wherein the buffer layer comprises a planarized upper surface, and the planarized upper surface has a surface roughness Ra of less than at least 5nm.

In some embodiments, the planarized upper surface of the buffer layer has a surface roughness Ra of less than at least 0.1nm. In some embodiments, the buffer layer provides an upper surface of the substrate, the substrate comprises a locally flat area with a surface roughness of less than at least 5nm, and the locally flat area has a surface uniformity with a variation from the surface roughness of less than 15%, wherein the channel and the source/drain regions are in the locally flat area, and the gate is on the locally flat area. In some embodiments, the active layer comprises a planarized upper surface and a surface roughness Ra of less than at least 5nm. In some embodiments, the upper surface of the active layer comprises an upper surface of the channel and an upper surface of the source/drain regions. In some embodiments, in a cross-sectional view of the transistor, the active layer has a uniform thickness and a surface roughness Ra of less than at least 0.1nm. In some embodiments, the gate comprises a planarized upper surface and a surface roughness Ra of less than at least 5nm. In some embodiments, in a cross-sectional view of the transistor, the gate has a uniform thickness and a surface roughness Ra of less than at least 0.1nm.

### BRIEF DESCRIPTION OF THE DRAWINGS

FIG. 1A is a top view of an intermediate product of a transistor of a light emitting device.

FIG. 1B is a cross-sectional view of the transistor along a line B-B’ in FIG. 1A.

FIG. 2A to FIG. 2C illustrate a manufacturing method of an intermediate product of a transistor according to some embodiments.

FIG. 3A to FIG. 3C illustrate a manufacturing method of an intermediate product of a transistor according to some embodiments.

FIG. 4 illustrates a schematic view of an intermediate stage structure of a light emitting device according to some embodiments.

FIG. 5 to FIG. 12 illustrate several operations of a method for preparing a light emitting device.

FIG. 13 illustrates a through-hole in an intermediate product of a light emitting device.

FIG. 14 to FIG. 17 illustrate several operations of a method for preparing a light emitting device.

FIG. 18 illustrates an intermediate product of a light emitting device.

FIG. 19 illustrates an intermediate product of a light emitting device.

FIG. 20 is a graph illustrating a relationship between a surface roughness of a planarized layer of a light emitting device and an emission rate.

FIG. 21 is a perspective view of a light emitting device.

FIG. 22 is an electrode array of the light emitting device shown in FIG. 21.

### DETAILED DESCRIPTION OF THE EMBODIMENTS

A structure of a light emitting device has at least two main tiers. One tier is configured as a light emitting tier, which includes an array of light emitting pixels and can provide luminescence for the device. The light emitting pixels may be made from organic or inorganic materials. The other tier is a circuit tier, which is electrically coupled with the light emitting tier and stacked vertically with it. The circuit tier supplies power and controls signals to the light emitting tier to display colors or patterns as needed.

Various approaches can be used to combine the two main tiers into an integrated device. One approach is to first form the circuit tier and then dispose the light emitting tier on the circuit tier. The circuit tier acts as a process starting substrate for forming the light emitting tier thereon. Another exemplary approach is to form the circuit tier and the light emitting tier separately on separate substrates, and then bond them to form an integrated light emitting device. However, regardless of which approach is chosen, the flatness of the contact surfaces on each side is crucial for forming the integrated light emitting device.

The present disclosure provides a solution for forming one or more components having a flat surface within the circuit tier to improve process yield. In some embodiments, the circuit tier includes a transistor, with one or more components of the transistor having flat surfaces. In some embodiments, a substrate is provided, using the flat upper surface of the substrate as a starting surface, so that the components of the transistor formed above have flat surfaces; in some embodiments, a planarization process may also be performed on the components of the transistor to further improve the electrical performance of the transistor, such as reducing leakage current. In some embodiments, a planarization process may be performed on an active layer on the substrate to provide a flat upper surface, ensuring that other components of the transistor formed above have flat surfaces; in some embodiments, a planarization process may also be performed on other components of the transistor to further enhance the electrical performance of the transistor.

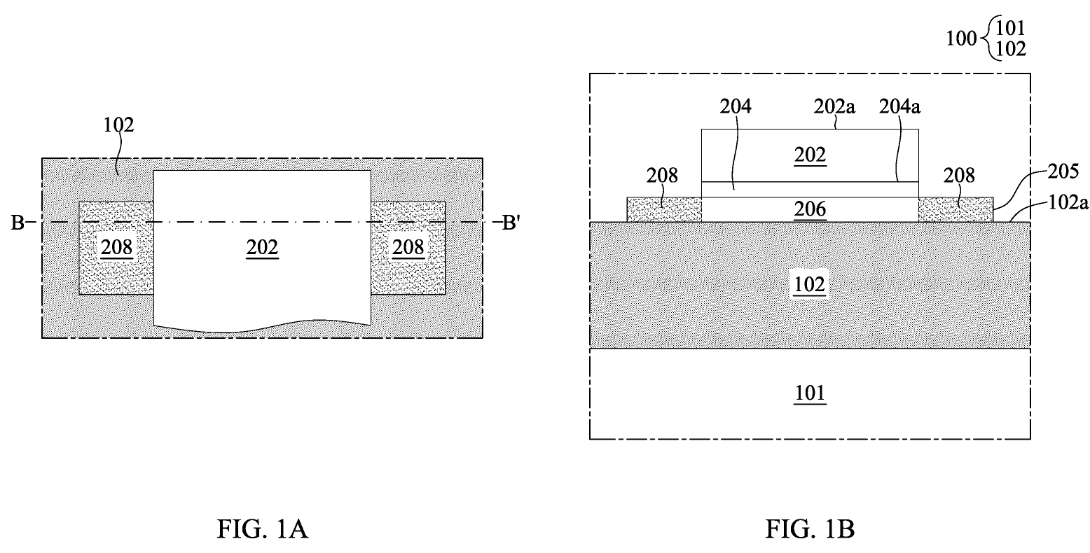

FIG. 1A is a top view illustrating an intermediate product of a transistor. FIG. 1B is a cross-sectional view of a transistor. In some embodiments, FIG. 1B illustrates a cross-sectional view along a line B-B’ in FIG. 1A. A circuit tier disposed on a substrate 100 may have several transistors, and FIG. 1A and FIG. 1B illustrate only one transistor. Each transistor comprises a substrate 100, a gate 202 over the substrate 100, and an active layer 205 between the substrate 100 and the gate 202.

In some embodiments, the substrate 100 comprises a base material 101 and a buffer layer 102 over the base material. The base material 101 may be glass, semiconductor material (such as silicon, III-V compound), or other suitable materials. In some embodiments, the base material 101 comprises graphene.

In some embodiments, a polymer matrix material may be used to form the base material 101. A bend radius of the base material 101 is not greater than about 3mm. In some embodiments, a minimum bend radius of the base material 101 is not greater than 10mm. The minimum bend radius is used to measure an inner curvature, which refers to a minimum radius that can bend the substrate 100 without kinking it, damaging it, or shortening its lifespan.

In some embodiments, the buffer layer 102 provides an upper surface of the substrate 100, and a gate dielectric layer 204 and the gate 202 are formed on the buffer layer 102. The buffer layer 102 may comprise a single layer or multiple layers of insulating material. In some embodiments, the buffer layer 102 comprises a single layer of silicon oxide (SiOx). In some embodiments, the buffer layer 102 is a multilayer structure formed of silicon nitride (SiNx) and silicon oxide (SiOx). The buffer layer 102 can enhance an adhesion between layers formed thereon and the base material 101 and block alkaline components leaking from the base material 101.

Furthermore, in some embodiments, the transistor (e.g., LTPS thin-film transistor) includes an active layer 205 on the buffer layer 102. The active layer 205 comprises semiconductor materials, which may be obtained from, for example, silicon or other elements selected from Group IV or Group III and Group V and through semiconductor material fabrication processes.

In some embodiments, the active layer 205 comprises polycrystalline silicon. Specifically, amorphous silicon (a-Si) material may be deposited on the buffer layer 102, and a dehydrogenation process and a crystallization process are performed to form polycrystalline silicon, which is then patterned to form the active layer 205, and ion doping (impurity doping) is performed on the active layer to define a channel 206 and source/drain regions 208 on opposites side of the channel 206.

Furthermore, the gate 202 is over the channel 206. The gate 202 may be made of conductive material, such as metal or silicide. In some embodiments, the gate 202 may be a composite structure that comprises multiple different layers, which may be identified under a microscope after applying an etchant. For simplicity, only partial areas of the gate 202 and the source/drain region 208 are shown.

In the transistor, the gate dielectric layer 204 is between the gate 202 and the channel 206. The gate dielectric layer 204 may be silicon oxide, silicon oxide-silicon nitride-silicon oxide (ONO), or high dielectric constant (high-k, having a dielectric constant greater than 10 or 12) materials, such as hafnium silicate, zirconium silicate, hafnium dioxide, and zirconium dioxide, etc. The source/drain region 208 is disposed on the opposite sides of the channel 206 to provide carriers.

In some cases, the buffer layer 102 may have an uneven surface due to the manufacturing process. For example, when the buffer layer 102 is fabricated under high-temperature conditions containing oxygen, crystallization may occur, forming protrusions and resulting in an uneven upper surface. As mentioned above, in some cases, the transistor comprises the gate 202, the channel 206, and the source/drain regions 208. The channel 206 and the source/drain regions 208 are made from a polysilicon active layer. Since the transistor is disposed over the buffer layer 102, an uneven surface of the buffer layer 102 would significantly affect the topology of components formed thereon. Furthermore, a buffer layer 102 with an irregular upper surface and uneven film thickness would affect the flatness of local polysilicon regions in the active layer, particularly the polysilicon channel 206. An uneven surface of the polysilicon channel 206 may cause the transistor to have a higher leakage current (Ioff).

According to some embodiments, after depositing the buffer material, a planarization process is performed on the surface of the material to produce a buffer layer 102 having a flat upper surface.

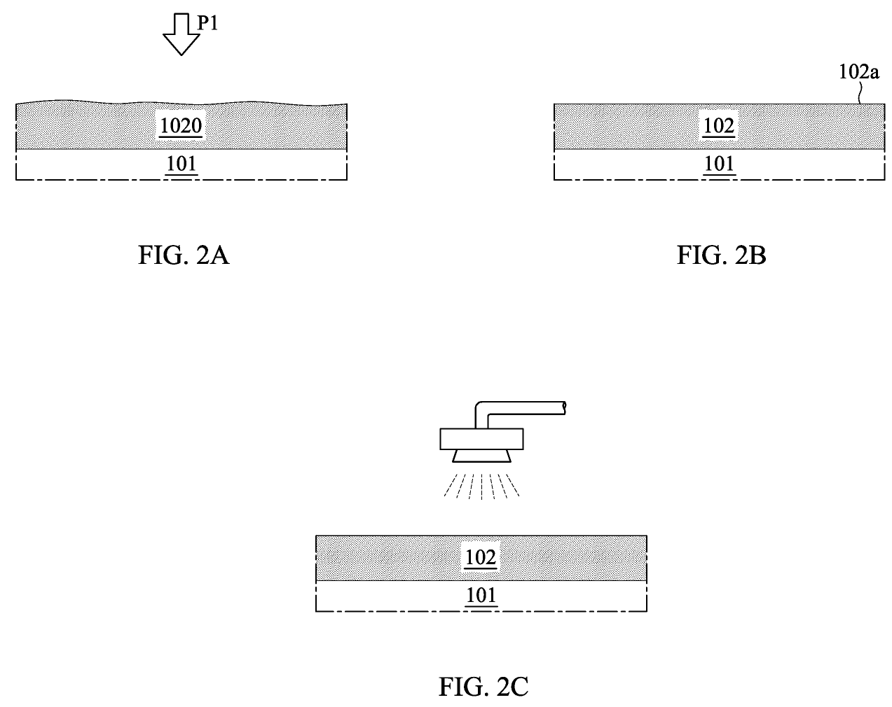

FIG. 2A to FIG. 2C illustrate a manufacturing method of an intermediate product of a transistor according to some embodiments. In some embodiments, FIG. 2A to FIG. 2C only illustrate the buffer layer region. According to some embodiments, as shown in FIG. 2A, a substrate 101 is provided, and a buffer material 1020 is formed over the substrate. As shown in FIG. 2B, a planarization process is performed on the buffer material 1020 to produce the buffer layer 102. The planarization process, such as a planarization operation of chemical mechanical polishing (CMP), removes irregular protrusions in the buffer material, resulting in the buffer layer 102 having a flat surface 102a (or upper surface 102a). A buffer layer 102 having a flat surface can improve the surface flatness of layers or components formed thereon, thereby enhancing the electrical performance of the transistor. For example, an active layer 205 (FIG. 1B, including the channel 206 and the source/drain regions 208 on opposite sides of the channel 206) formed over the flat buffer layer 102 also has a flat or substantially flat surface, reducing the leakage current of the transistor.

Furthermore, in some embodiments, a surface roughness Ra of the buffer layer 102 after the planarization operation (e.g., CMP) is 15nm or less, for example, less than 14nm, less than 13nm, less than 12nm, less than 11nm, less than 10nm, less than 9nm, less than 8nm, less than 7nm, or less than 6nm. In some embodiments, the surface roughness Ra of the buffer layer 102 after the planarization operation (e.g., CMP) is 5nm or less, for example, less than 4.5nm, less than 4nm, less than 3.5nm, less than 3nm, less than 2.5nm, or less than 2nm. Furthermore, in some embodiments, the surface roughness Ra of the buffer layer 102 after the planarization operation (e.g., CMP) is 1.5nm or less, for example, 1.4nm or less, 1.3nm or less, 1.2nm or less, 1.1nm or less, 1.0nm or less, 0.9nm or less, 0.8nm or less, 0.7nm or less, 0.6nm or less, 0.5nm or less, 0.4nm or less, 0.3nm or less, 0.2nm or less, 0.1nm or less, 0.09nm or less, 0.08nm or less, 0.07nm or less, 0.06nm or less, 0.05nm or less, 0.04nm or less, 0.03nm or less, 0.02nm or less, or 0.01nm or less, preferably 0nm. In some embodiments, the surface roughness Ra of the buffer layer 102 after the planarization operation (e.g., CMP) may be within a range of the aforementioned two values, for example, between about 5nm and about 0.1nm, between about 4nm and about 0.05nm, between about 3nm and about 0.03nm, between about 2nm and about 0.01nm, between about 1.5nm and about 0.01nm, between about 1.2nm and about 0.01nm, between about 1.0nm and about 0.01nm, or other ranges. Furthermore, the surface uniformity is defined by the degree of variation (Unit: %) of each point on the material surface from an average surface roughness value. In some embodiments, the surface uniformity of the buffer layer 102 after the planarization operation (e.g., CMP) is such that the degree of variation is less than 15%, for example, less than 14%, less than 13%, less than 12%, less than 11%, less than 10%, less than 9%, less than 8%, less than 7%, less than 6%, less than 5%, less than 4%, less than 3%, less than 2%, or less than 1%.

According to some embodiments, as shown in FIG. 2C, after performing a planarization process (such as CMP) on the buffer material 1020, an optional cleaning process may be performed to clean the surface of the buffer material 1020, removing polishing slurry and particles generated after polishing from the surface of the buffer material 1020.

Furthermore, the active layer 205 in the transistor (FIG. 1B, including the channel 206 and the source/drain region 208 on opposite sides of the channel 206) may also have an uneven surface due to the manufacturing process. In some embodiments where the active layer 205 comprises polysilicon, when depositing amorphous silicon on the buffer layer 102 and performing the dehydrogenation process and the crystallization process to form polysilicon, crystallization may cause the upper surface 205a of the active material 2050 to be uneven, resulting in an overall uneven film thickness of the active layer 205 and irregular distribution of grain boundaries. If the surface of the active layer 205 is rough and the film thickness is uneven, it will cause the channel 206 and the source/drain region 208 formed thereon to have rough surfaces and uneven film thickness. An uneven surface and thickness of the channel 206 will cause an uneven electric field, and the irregular distribution of grain boundaries in the channel 206 will also lead to leakage current. Additionally, the unevenness of the active layer 205 also affects the topology of the gate 202 subsequently formed thereon. These defects all lead to reduced performance of the transistor.

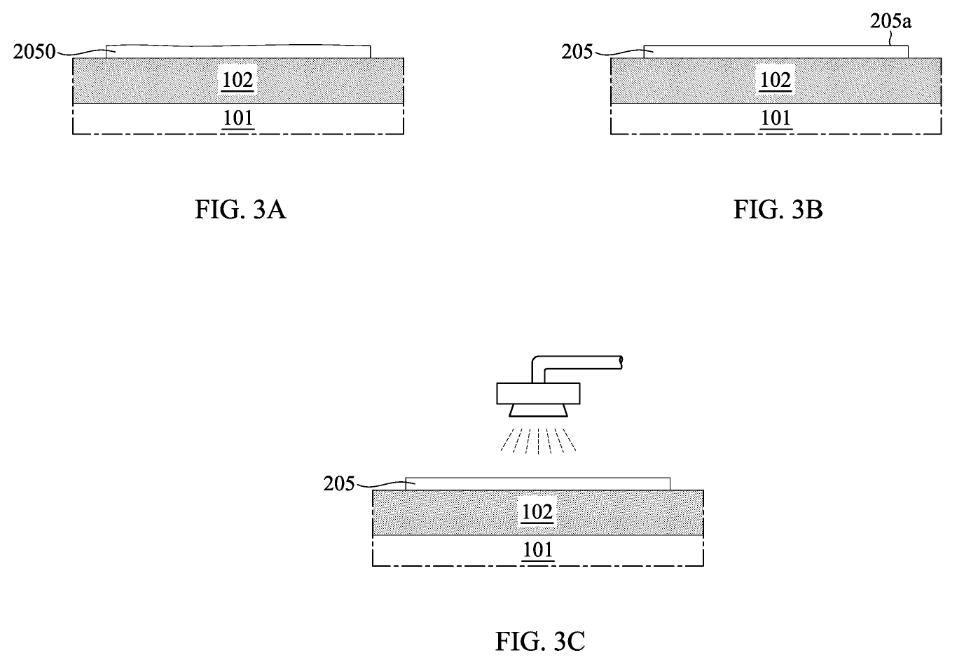

FIG. 3A to FIG. 3C illustrate a manufacturing method of an intermediate product of a transistor according to some embodiments. In some embodiments, FIG. 3A to FIG. 3C only illustrate the active layer region.

As shown in FIG. 3A, a substrate 101 is provided, a buffer layer 102 is formed over the substrate, and an active material 2050 is formed over the buffer layer 102. In some embodiments, the buffer layer 102 may be formed using the manufacturing method shown in FIG. 2A to FIG. 2C. According to some embodiments, after depositing the active material 2050, a planarization operation, such as a chemical mechanical polishing (CMP) process, may be performed on the surface of the active material 2050 to remove irregular protrusions in the active material 2050. As shown in FIG. 3B, the resulting active layer 205 can achieve a flat upper surface 205a and uniform film thickness, thereby reducing leakage current. Furthermore, the active layer 205 after the planarization process can provide a flat surface for disposing the subsequently formed gate 202.

In some embodiments, after forming the buffer material and optionally performing a cleaning process to form the buffer layer 102, the active material 2050 may be formed over the buffer layer 102, which may have an uneven upper surface. By performing a planarization process on the surface of the active material 2050, the manufactured transistor can have a flat channel 206 and source/drain region 208 and provide a flat surface (upper surface 205a) for disposing other components of the subsequently formed transistor.

In some embodiments, the surface roughness Ra of the active layer 205 after a planarization operation (e.g., CMP) is 5nm or less, for example, less than 4.5nm, less than 4 nm, less than 3.5nm, less than 3nm, less than 2.5nm, or less than 2nm. Furthermore, in some embodiments, the surface roughness Ra of the active layer 205 after a planarization operation (e.g., CMP) is 2nm or less, for example, 1.9nm or less, 1.8nm or less, 1.7nm or less, 1.6nm or less, 1.5nm or less, 1.4nm or less, 1.3nm or less, 1.2nm or less, or 1.1nm or less. In some embodiments, the surface roughness Ra of the active layer 205 after planarization (e.g., CMP) is 1nm or less, for example, 0.9nm or less, 0.8nm or less, 0.7nm or less, 0.6nm or less, 0.5nm or less, 0.4nm or less, 0.3nm or less, 0.2nm or less, or 0.1nm or less. In some embodiments, the surface roughness Ra of the active layer 205 after planarization (e.g., CMP) may reach 0.09nm or less, 0.08nm or less, 0.07nm or less, 0.06nm or less, 0.05 nm or less, 0.04 nm or less, 0.03 nm or less, 0.02 nm or less, or 0.01 nm or less, preferably 0 nm. Furthermore, in some embodiments, the surface roughness Ra of the active layer 205 after planarization (e.g., CMP) may be within a range of the aforementioned two values, for example, between about 2nm and about 0.02nm, between about 1.5nm and about 0.01nm, between about 1.2nm and about 0.01nm, or other ranges. The actual value of the surface roughness Ra of the active layer 205 in the embodiments may vary depending on its formation thickness but still has a relatively high degree of flatness. The surface uniformity is defined by the degree of variation (Unit: %) of each point on the material surface from an average surface roughness value. In some embodiments, the surface uniformity of the active layer 205 after a planarization operation (e.g., CMP) is such that the degree of variation is less than 15%, for example, less than 14%, less than 13%, less than 12%, less than 11%, less than 10%, less than 9%, less than 8%, less than 7%, less than 6%, less than 5%, less than 4%, less than 3%, less than 2%, or less than 1%.

According to some embodiments, as shown in FIG. 3C, after performing a planarization process (such as CMP) on the active material 2050, a cleaning process may be optionally performed to clean the surface of the active material 2050, removing the polishing slurry and particles generated after polishing from the surface.

Furthermore, the gate dielectric layer 204 in the transistor may also have an uneven surface due to the manufacturing process. According to some embodiments, fabricating the gate dielectric layer 204 under high-temperature conditions containing oxygen may cause crystallization, resulting in an uneven upper surface 204a (FIG. 1B) and non-uniform overall film thickness, also causing irregular distribution of grain boundaries, which in turn leads to gate leakage current. Additionally, the unevenness of the gate dielectric layer 204 also affects the topology of the gate 202 subsequently disposed thereon. These defects all lead to reduced performance of the transistor.

According to some embodiments, after depositing the gate dielectric material, a planarization operation such as chemical mechanical polishing (CMP) may be performed on the surface of the gate dielectric material to remove irregular protrusions in the gate dielectric material, resulting in a gate dielectric layer 204 having a flat upper surface 204a and uniform film thickness, thereby reducing leakage current. Furthermore, the gate dielectric layer 204 after the planarization process can provide a flat surface for disposing the subsequently formed gate 202.

In some embodiments, the surface roughness Ra of the gate dielectric layer 204 after a planarization operation (e.g., CMP) is 2nm or less, for example, 1.9nm or less, 1.8nm or less, 1.7nm or less, 1.6nm or less, 1.5nm or less, 1.4nm or less, 1.3nm or less, 1.2nm or less, or 1.1nm or less. In some embodiments, the surface roughness Ra of the gate dielectric layer 204 after planarization (e.g., CMP) is 1nm or less, for example, 0.9nm or less, 0.8nm or less, 0.7nm or less, 0.6nm or less, 0.5nm or less, 0.4nm or less, 0.3nm or less, 0.2nm or less, or 0.1nm or less. In some embodiments, the surface roughness Ra of the gate dielectric layer 204 after planarization (e.g., CMP) may reach 0.09nm or less, 0.08nm or less, 0.07nm or less, 0.06nm or less, 0.05nm or less, 0.04nm or less, 0.03nm or less, 0.02nm or less, or 0.01nm or less, preferably 0nm. Furthermore, in some embodiments, the surface roughness Ra of the gate dielectric layer 204 after planarization (e.g., CMP) may be within a range of the aforementioned two values, for example, between about 2nm and about 0.02nm, between about 1.5nm and about 0.01nm, between about 1.2nm and about 0.01nm, or other ranges. The actual value of the surface roughness Ra of the gate dielectric layer 204 in the embodiments may vary depending on its formation thickness but still has a relatively high degree of flatness. Surface uniformity is defined by the degree of variation (Unit: %) of each point on the material surface from an average surface roughness value. In some embodiments, the surface uniformity of the gate dielectric layer 204 after a planarization operation (e.g., CMP) is such that the degree of variation is less than 15%, for example, less than 14%, less than 13%, less than 12%, less than 11%, less than 10%, less than 9%, less than 8%, less than 7%, less than 6%, less than 5%, less than 4%, less than 3%, less than 2%, or less than 1%.

In some embodiments, after performing a planarization process (such as CMP) on the gate dielectric material, a cleaning process can be optionally performed to clean the surface of the gate dielectric material, removing the polishing slurry and particles generated after polishing from the surface.

Furthermore, according to some embodiments, the gate 202 (FIG. 1B) in the transistor is a polysilicon gate. The gate 202 in the transistor may also cause crystallization due to the high-temperature manufacturing process, making the upper surface 202a of the gate 202 uneven and affecting the uniformity of the overall film thickness, also causing irregular distribution of grain boundaries. These protrusions formed on the surface of the gate 202, like defects in the channel 206, will affect the component characteristics of the transistor, such as increasing leakage current.

According to some embodiments, after depositing the gate material, a planarization operation such as chemical mechanical polishing (CMP) may be performed on the material surface to remove irregular protrusions in the gate material, resulting in a gate 202 having a flat upper surface 202a and uniform or substantially uniform film thickness, thereby improving the gate-induced drain leakage (GIDL) phenomenon.

In some embodiments, the flatness of the gate 202 corresponds to the flatness of the gate dielectric layer 204. In some embodiments, the flatness of the gate 202 differs from the flatness of the gate dielectric layer 204. In some embodiments, the surface roughness Ra of the gate 202 after a planarization operation (e.g., CMP) is 15nm or less, for example, less than 14nm, less than 13nm, less than 12nm, less than 11nm, less than 10nm, less than 9nm, less than 8nm, less than 7nm, or less than 6nm. In some embodiments, the surface roughness Ra of the gate 202 after a planarization operation (e.g., CMP) is 5 nm or less, for example, less than about 4.5nm, or less than about 4.0nm, less than 3.5nm, less than 3nm, less than 2.5nm, or less than about 2nm. Furthermore, in some embodiments, the gate 202 after a planarization operation (e.g., CMP) is 1.5nm or less, for example, 1.4nm or less, 1.3nm or less, 1.2nm or less, 1.1nm or less, 1.0nm or less, 0.9nm or less, 0.8nm or less, 0.7nm or less, 0.6nm or less, 0.5nm or less, 0.4nm or less, 0.3nm or less, 0.2nm or less, 0.1nm or less, 0.09nm or less, 0.08 nm or less, 0.07 nm or less, 0.06 nm or less, 0.05nm or less, 0.04nm or less, 0.03nm or less, 0.02nm or less, or 0.01nm or less, preferably 0 nm. In some embodiments, the surface roughness Ra of the gate 202 after a planarization operation (e.g., CMP) may be within a range of the aforementioned two values, for example, between about 5nm and about 0.1nm, between about 4nm and about 0.05nm, between about 3nm and about 0.03nm, between about 2nm and about 0.01nm, between about 1.5nm and about 0.01nm, between about 1.2nm and about 0.01nm, between about 1.0nm and about 0.01nm, between about 0.5nm and about 0.01nm, or other ranges. The actual value of the surface roughness Ra in the embodiments may vary depending on the formation thickness of the gate 202 but still has a relatively high degree of flatness. For example, in some embodiments, the thickness of the gate 202 is 10nm to 80nm, 15nm to 70nm, or 20nm to 60nm, with a surface roughness Ra between about 5nm and about 0.1nm. Furthermore, surface uniformity is defined by the degree of variation (Unit: %) of each point on the material surface from an average surface roughness value. Furthermore, in some embodiments, the surface uniformity of the gate 202 after a planarization operation (e.g., CMP) is such that the degree of variation is less than 15%, for example, less than 14%, less than 13%, less than 12%, less than 11%, less than 10%, less than 9%, less than 8%, less than 7%, less than 6%, less than 5%, less than 4%, less than 3%, less than 2%, or less than 1%.

In some embodiments, after the planarization process (such as CMP) of the gate material, an optional cleaning process may be performed to clean the surface of the gate material and remove the polishing slurry and particles generated after polishing.

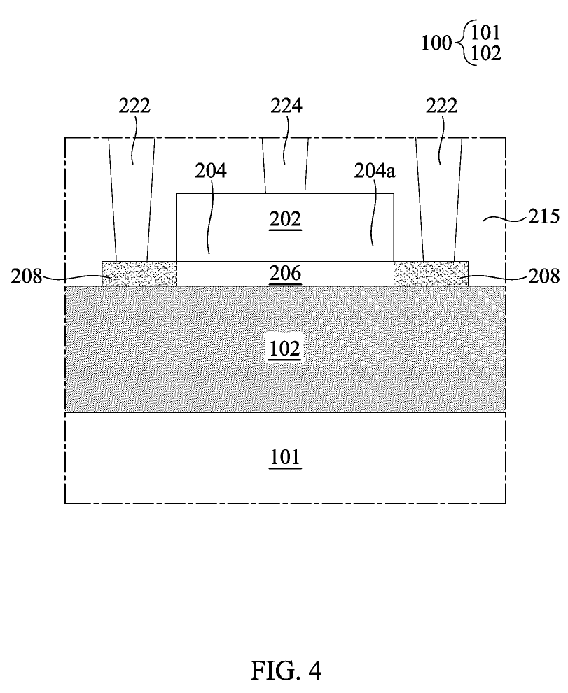

FIG. 4 illustrates a schematic diagram of an intermediate stage structure of a light emitting device according to some embodiments. FIG. 4 is only an illustration of the transistor region. According to some embodiments, after forming the transistor, conductive components connected to the transistor are also formed. In some embodiments, the conductive components may comprise conductive vias 222 and 224. One end of the conductive via 222 is connected to the source/drain region 208 of the transistor, and one end of the conductive via 224 is connected to the gate 202 of the transistor or the capacitor metal (not shown in FIG. 4). The conductive components may comprise some traces that serve as interconnects between different transistors or other electronic components in circuit tiers.

In some embodiments, the buffer layer 102, the active layer 205 (including the channel 206 and the source/drain region 208), the gate dielectric layer 204, and the gate 202 are fabricated through a planarization process such as CMP and may have a flat surface and high film thickness uniformity, thereby significantly reducing leakage current and improving the electrical performance of the transistor. In some embodiments, the substrate 100 comprises a locally flat area (i.e., active region), the buffer layer 102 provides a flat upper surface of the locally flat area of the substrate 100, the channel 206 and source/drain region 208 are in the locally flat area, and the gate 202 is on the locally flat area, which can reduce the leakage current of the transistor.

In some comparative examples of transistors, an unplanarized buffer layer 102 results in the transistor having a larger leakage current, whereas for some embodiments of transistors, the planarized buffer layer 102 results in the transistor having a smaller leakage current. In some embodiments of transistors, the planarized buffer layer 102 and the planarized polysilicon channel 206 result in the transistor having even smaller leakage current.

In some comparative examples of transistors, for example, when the width/length of the gate 202 is 0.4μm / 0.8μm, the unplanarized polysilicon channel 206 results in the transistor having a larger leakage current, which may reach about 1×10^(-12) to 10×10^(-12) amperes. In contrast, for some embodiments of transistors, the planarized polysilicon channel 206 results in the transistor having a smaller leakage current, for example, when the width/length of the gate 202 is 0.4μm / 0.8μm, the leakage current of the transistor can be reduced to less than 1×10^(-12) amperes (below the limits of the measuring machine).

In some embodiments, the present disclosure also provides a topmost flat surface of a circuit tier. This topmost flat surface serves as a starting surface for disposing a light emitting pixel array thereon. In some embodiments, the arrangement of pixels in the array is determined through photolithography operations. In the present disclosure, the arrangement of pixels refers to the position, light emitting area, or other geometric characteristics of each pixel, which are defined during the photolithography operation.

In some embodiments, a pixel array is formed by creating an array of conductive pads on the topmost surface of the circuit tier. The conductive sheet may be patterned through at least photolithography or etching operations to form the array of conductive pads. The topmost surface is at least partially covered by the conductive pads. The conductive pads may be electrically connected to the wire in the circuit tier through several conductive vias. A photomask is disposed to substantially cover areas not occupied by the conductive pads, and a trench is formed on a conductive pad. An emission layer or other layers (such as carrier transport or injection layers) may be placed in the trench to form a light emitting pixel. In some embodiments, before placing the photomask, the carrier transport or injection layer is placed over the conductive pads and the aforementioned unoccupied areas. Since photolithography operations are used in multiple process steps to form the light emitting pixel array, this illustrates that besides the surface flatness of components (such as transistors) within the circuit tier, the flatness of the topmost surface of the circuit tier is also crucial for process yield.

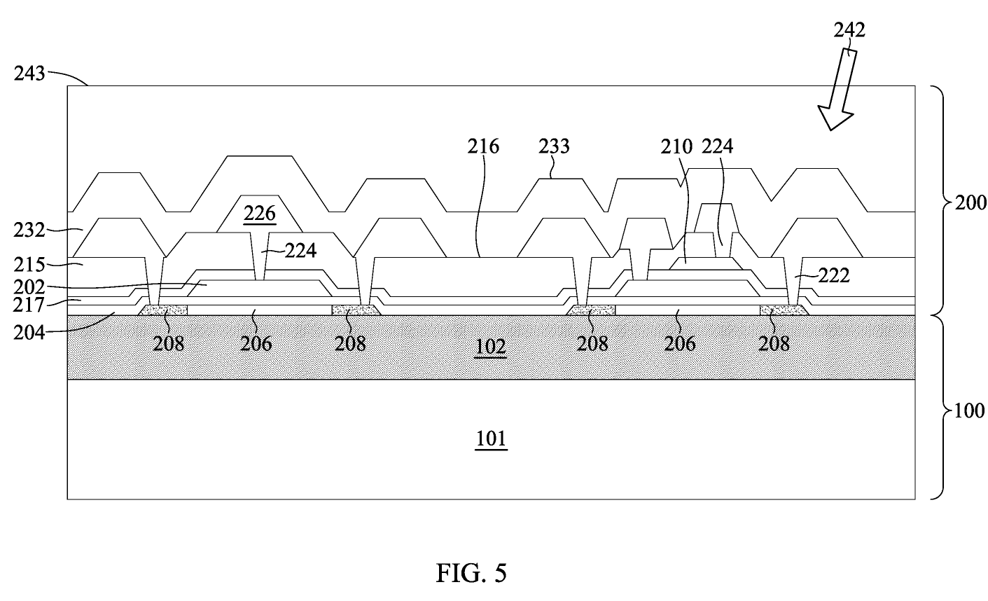

FIG. 5 illustrates an operation for forming a light emitting device according to some embodiments of the present disclosure. Material and manufacturing methods of components of the transistor, such as the substrate 101, the buffer layer 102, the channel 206, and the source/drain region 208 (active layer), the gate 202 (e.g., providing a flat upper surface) may refer to the aforementioned content and will not be repeated here.

After forming the transistor, conductive components connected to the transistor are also formed. The conductive components may comprise some conductive vias 222, one end of which is connected to the source/drain region 208 of the transistor. The conductive components may comprise some conductive vias 224, one end of which is connected to the gate 202 of the transistor or the capacitor metal 210. The conductive components may comprise some wires 226, which serve as interconnects between other electronic components in different transistors or circuit tiers 200.

A dielectric layer 215 is placed between the transistor and the wire 226. In some embodiments, the dielectric layer 215 may comprise more than one layer as shown in FIG. 5. The conductive vias 222 and 224 pass through the dielectric layer 215, respectively. The dielectric layer 215 conforms to the topology of the transistors and capacitors disposed on the substrate 100. Therefore, the upper surface 216 of the dielectric layer 217 may be undulating and follows the topology of the transistors and capacitors below the dielectric layer 215.

The total height of each conductive via may vary because the penetration depth of each path is determined by the total thickness of the dielectric layer 215 and other thin layers beneath it. For example, the total height of the vias 224 connected to the capacitor metal 210 is shorter than the vias 224 connected to the gate 202 since the vias 224 connected to the gate 202 must also penetrate the dielectric layer 217 between the gate 202 and the capacitor metal 210. Similarly, the total length of the vias 224 connected to the gate 202 is shorter than the vias 222 connected to the source/drain region 208.

Another dielectric layer 232 is disposed to cover the wire 226. In some embodiments, the dielectric layer 232 comprises silicon nitride, which offers better moisture and acid resistance than the dielectric layer 215. In some embodiments, the dielectric layer 232 conforms to the conductive vias and wire 226 to provide better protection for the wire 226. Therefore, similar to the dielectric layer 215, an upper surface 233 of the dielectric layer 232 is uneven and follows the topology of the underlying conductive vias and wires.

A planarization layer 242 may be optionally provided on the upper surface 233 of the dielectric layer 232. Compared to the dielectric layers 232 and 215, the planarization layer 242 has better gap-filling capabilities. Thus, if there are any depressions on the upper surface 233, the planarization layer 242 can fill these depressions to minimize the roughness of the upper surface 233. Furthermore, the planarization layer 242 can also provide a flat surface 243 for operations. In some embodiments, the planarization layer 242 is a black material (BM). In some embodiments, the planarization layer 242 is a spin-on glass (SOG) containing inorganic materials such as silicon oxide or silicon oxynitride. A thickness of the planarization layer 242 is between about 400nm and about 700nm.

The planarization layer 242 may be formed using various methods, including vapor deposition, sputtering, spin coating, and atomic layer deposition. In some embodiments, the planarization layer 242 is also a dielectric layer and may be made from organic or inorganic materials. In one embodiment, the planarization layer 242 is made of black material, which can substantially absorb visible light.

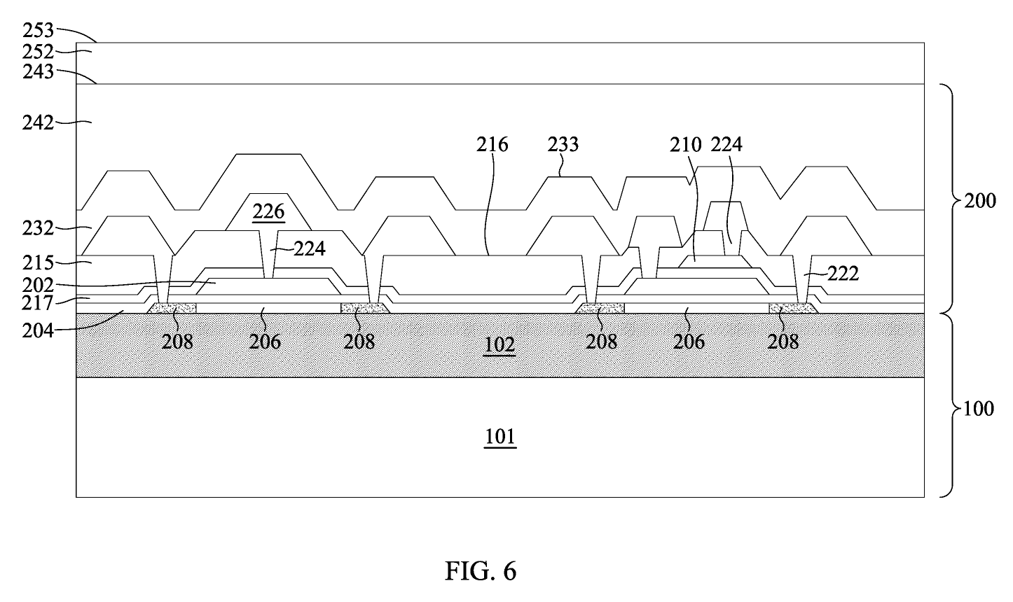

Another dielectric layer 252 may be optionally provided on the planarization layer 242, as shown in FIG. 6. The dielectric layer 252 is made from a material different from the planarization layer 242. One reason for using different materials for the dielectric layer 252 and the planarization layer 242 is to increase the selectivity between the dielectric layer 252 and the planarization layer 242 during some subsequent etching operations.

In one embodiment, the dielectric layer 252 is made from inorganic material, while the planarization layer 242 is made from organic material. The dielectric layer 252 may be made from silicon oxide, silicon nitride, silicon oxynitride, or other suitable materials. The dielectric layer 252 may be optionally coated on the planarization layer 242. In one embodiment, the planarization layer 242 is made from inorganic material, and no additional dielectric layer 252 is needed.

In some embodiments, the dielectric layer 252 has better resistance to O₂ plasma than the planarization layer 242. The dielectric layer 252 also has better resistance to PR stripping solutions than the planarization layer 242.

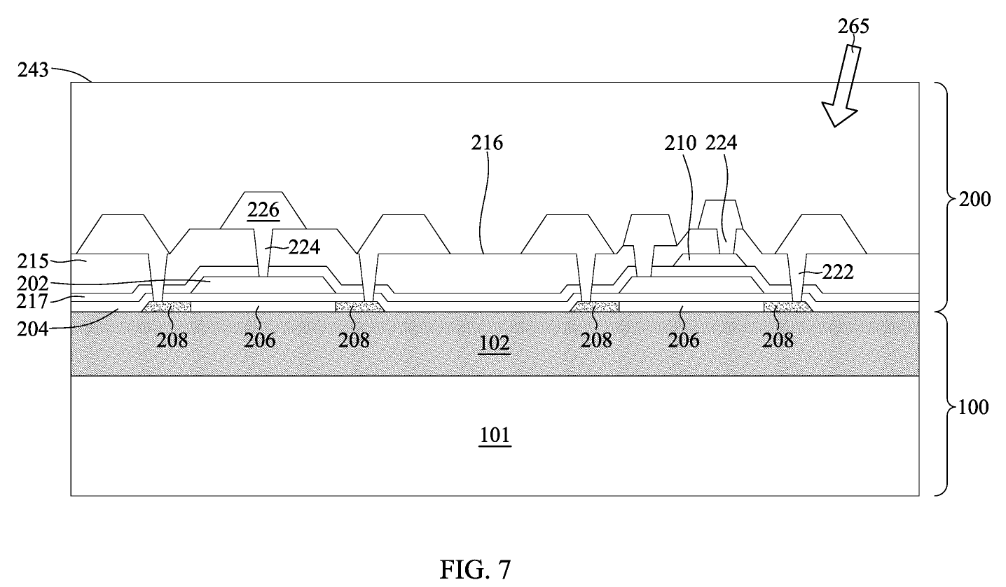

FIG. 7 illustrates another embodiment for forming a covered transistor and capacitor. Compared to the embodiments described in FIG. 5 and FIG. 6, the embodiment in FIG. 7 uses only one layer of dielectric layer 265 to cover the transistor and capacitor. The dielectric layer 265 is in direct contact with the transistor or capacitor. The dielectric layer 265 may be made from inorganic material.

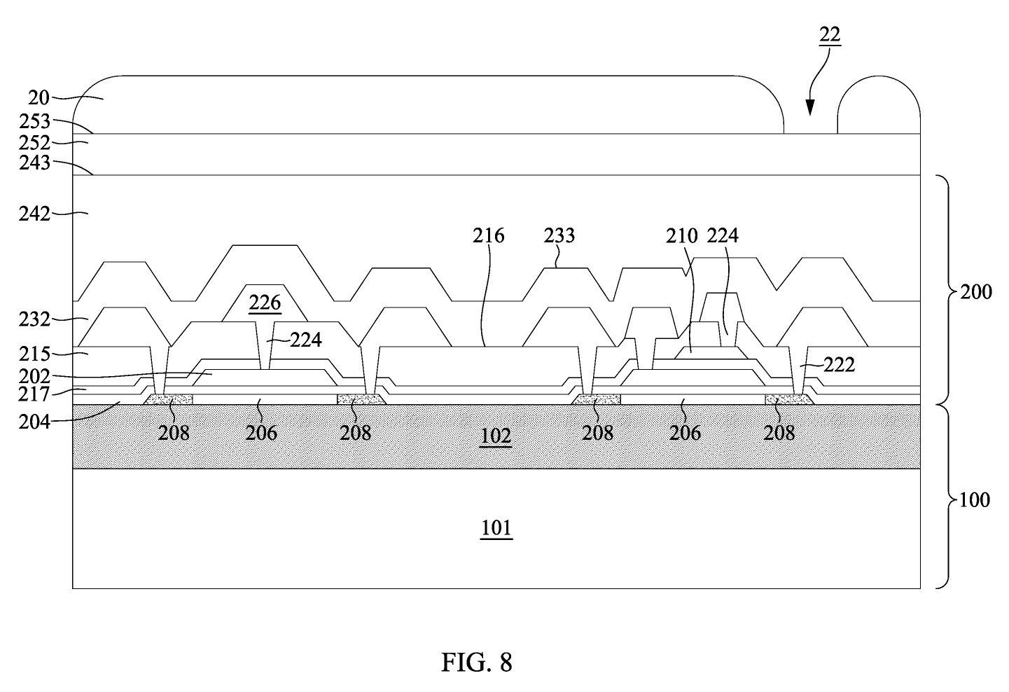

FIG. 8 illustrates an operation for forming an opening in the dielectric layer at the circuit tier shown in FIG. 6. A mask 20 is disposed to cover a surface 253 of the dielectric layer 252. The mask 20 may comprise a photosensitive material. The mask 20 is patterned to expose a portion of the surface 253. A photolithography process may be used to pattern the photosensitive mask 20, which comprises exposure, development, and other suitable operations.

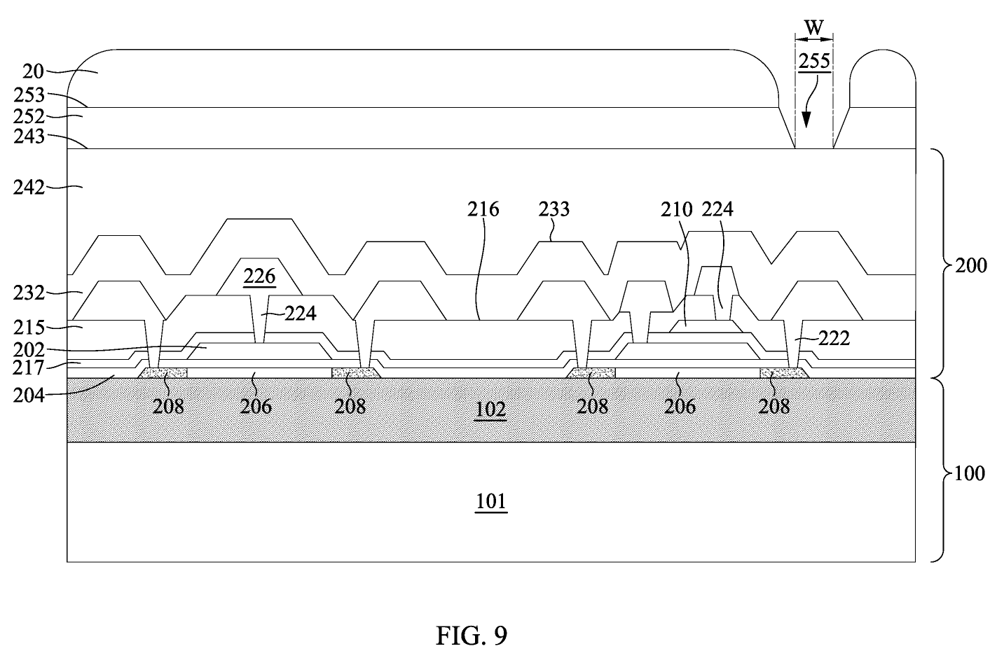

After forming a through-hole 22 in the portion of the surface 253 in the mask 20, a portion of the dielectric layer 252 is removed to form a through-hole 255 in the dielectric layer 252, as shown in FIG. 9. A portion of the planarization layer 242 is exposed through the through-hole 255. In some embodiments, the through-hole 255 is trapezoidal, and its maximum height gradually decreases from top towards the planarization layer 242. Sidewalls of the through-hole 255 may be inclined from the top towards the planarization layer 242 or may be curved with an arcuate surface.

Anisotropic etching may be used to form the through-hole 255. During the anisotropic etching process, an etchant plasma is formed in the chamber and directed towards the substrate 100. The etchant plasma may comprise fluorine, carbon, or silicon. During the etching process, a bias may be applied to the substrate 100.

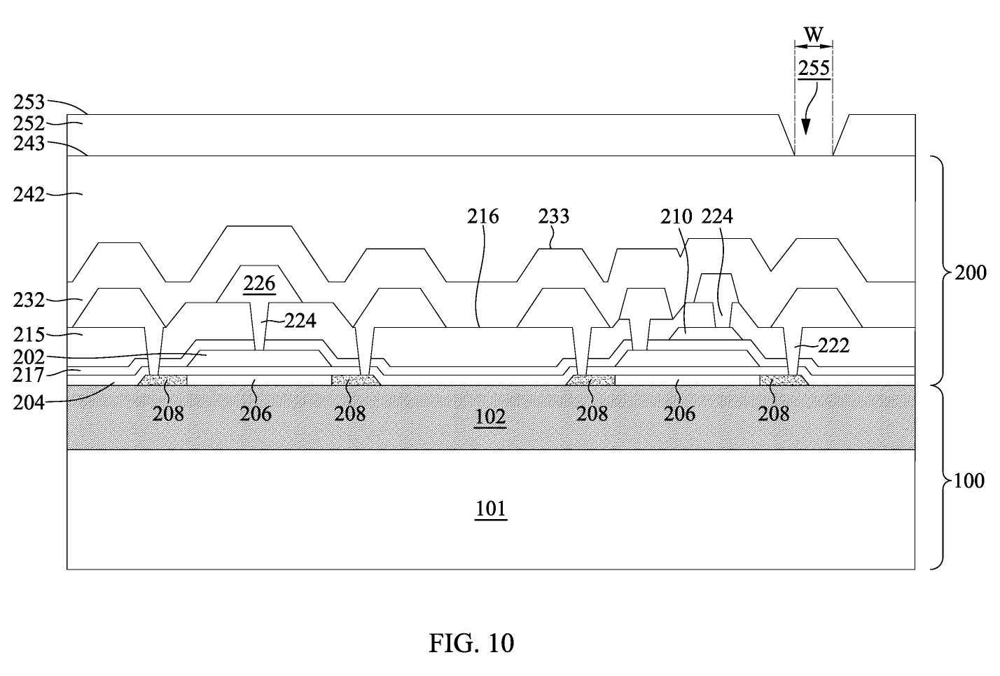

In some embodiments, after forming the through-hole 255 in the dielectric layer 252, the mask 20 is removed, as shown in FIG. 10. The patterned dielectric layer 252 may be used as a mask to define the via hole in the planarization layer 242. A maximum bottom width W of the through-hole 255 is used to define the size of the via hole formed in the planarization layer 242. Disposing the dielectric layer 252 on the planarization layer 242 can reduce the critical dimension of the via hole in the planarization layer 242 to be smaller than the size of the mask hole 22 defined in the photolithography process. The bottom width W may be gradually reduced from top to bottom by controlling the removal operation shown in FIG. 9. The taper angle of the through-hole 255 may be adjusted to the desired value by regulating parameters in the removal operation, such as changing the RF power, the bias applied to the substrate 100, the chamber pressure, etc.

After forming the through-hole 255 in the dielectric layer 252, the dielectric layer 252 becomes a hard mask on the planarization layer 242. As mentioned above, the bottom width W determines the size of the through-hole to be formed in the planarization layer 242. In some embodiments, the bottom width W is the maximum size of the through-hole in the planarization layer 242.

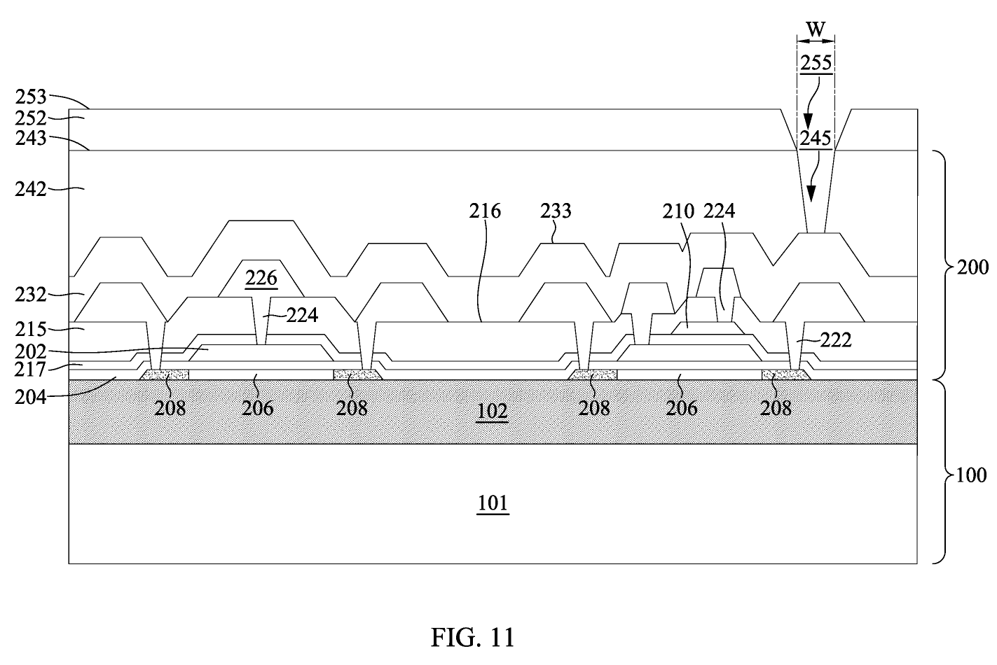

If the planarization layer 242 substantially contains organic material, oxygen may be introduced for top-down etching on the planarization layer 242. Before performing the top-down etching, the oxygen is ionized and converted into plasma. FIG. 11 illustrates a through-hole 245 formed in the planarization layer 242 after the top-down etching. Sidewalls of the through-hole 245 may taper from top to bottom (i.e., the top width is the widest). If the dielectric layer 232 is made of inorganic material, the oxygen plasma etching will stop at the dielectric layer 232.

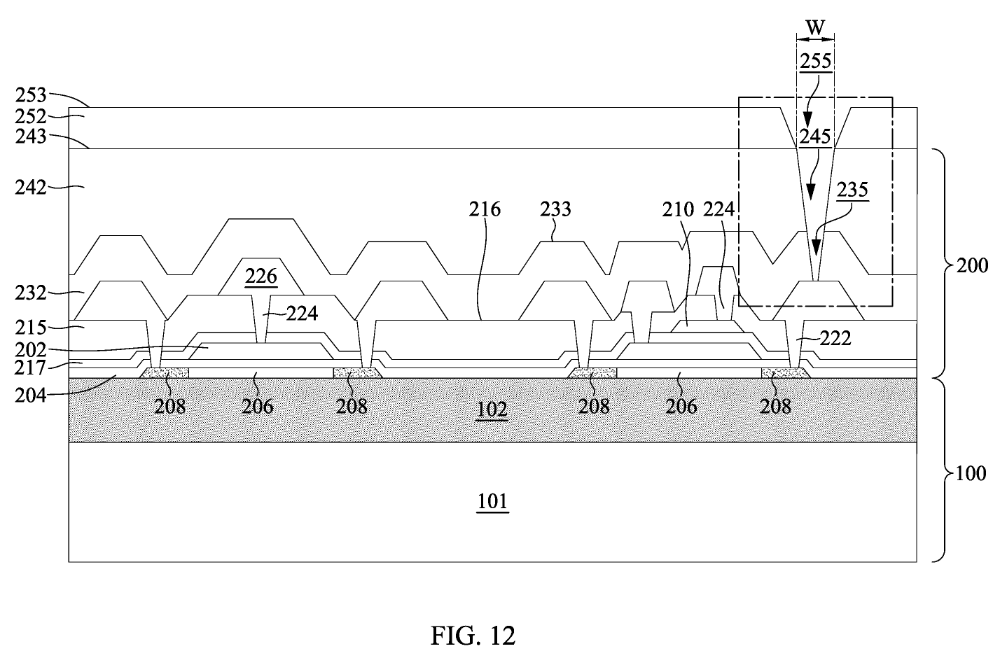

In some embodiments, the dielectric layer 232 is silicon oxide that is resistant to oxygen plasma. The etchant is converted from oxygen plasma to an oxide etchant to form a through-hole through the dielectric layer 232. A through-hole 235 is formed in the dielectric layer 232, as shown in FIG. 12. The through-hole 235 exposes a portion of the wire or conductive via. In some embodiments, the exposed surface of the wire or conductive via (i.e., the surface not covered by the dielectric layer 232) is lower than the lower surface 234 of the dielectric layer since a portion of the wire or conductive via is removed by the oxide etchant.

In some embodiments, the taper angle of through-hole 235 is different from the taper angle of through-hole 245. The sidewall slope of through-hole 235 may be greater than the taper angle of through-hole 245. In some embodiments, the sidewall slope of through-hole 245 may be greater than the taper angle of through-hole 255. In some embodiments, the above three through-holes have the same taper angle.

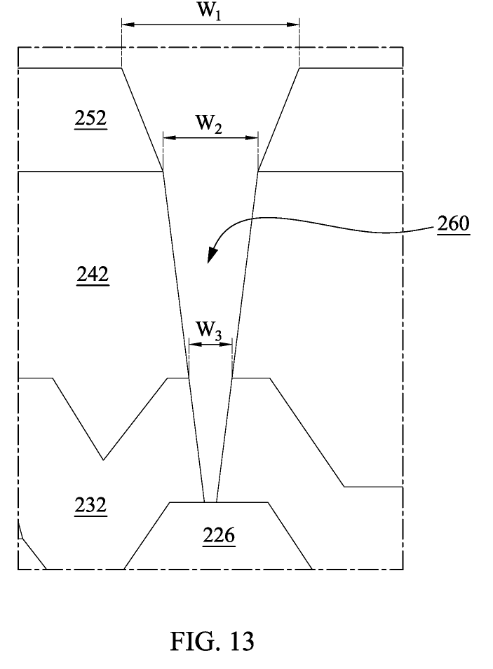

FIG. 13 is an enlarged view of the through-holes shown in FIG. 12. The dielectric layer 252 may be a silicon nitride or silicon oxide film. In one embodiment, the total thickness of the dielectric layer 252 is between about 40 m and about 130nm. In one embodiment, the total thickness of the dielectric layer 252 is between about 60nm and about 120nm. In one embodiment, the total thickness of the dielectric layer 252 is between about 80nm and about 115nm.

The planarization layer 242 may be an organic black material. In one embodiment, the total thickness of the dielectric layer 242 is between about 500nm and about 900nm. In one embodiment, the total thickness of the dielectric layer 242 is between about 600nm and about 850nm. In one embodiment, the total thickness of the dielectric layer 242 is between about 450nm and about 800nm.

The dielectric layer 232 may be a silicon nitride or silicon oxide film. In one embodiment, the total thickness of the dielectric layer 232 is between about 150nm and about 425nm. In one embodiment, the total thickness of the dielectric layer 232 is between about 100nm and about 600nm. In one embodiment, the total thickness of the dielectric layer 232 is between about 150nm and about 400nm.

The through-holes 235, 245, and 255 together form a through via 260 in the circuit hierarchy. The through via 260 has a first width W₁, which is the dimension at the topmost part of the through via 260. The through via 260 has a second width W₂, which is the dimension at the interface between the dielectric layer 242 and the dielectric layer 252. The through via 260 has a third width W₃, which is the dimension at the bottommost part of the through via 260. In some embodiments, the first width W₁ is greater than the second width W₂, and the second width W₂ is greater than the third width W₃. In some embodiments, the first width W₁ is less than about 0.5μm, and the third width W₃ is about 80% of the first width W₁ or less than the first width W₁.

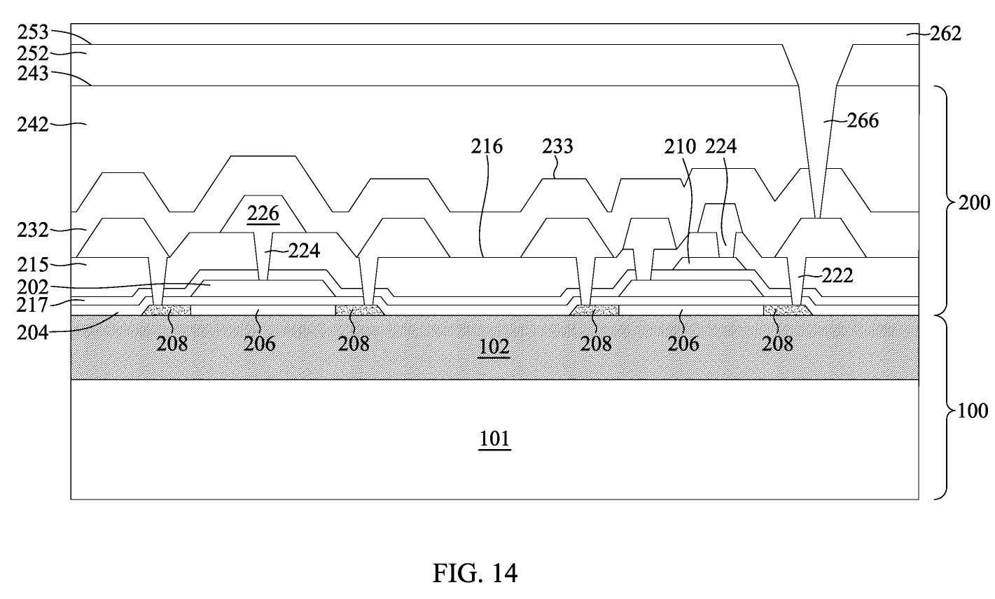

A conductive material 262 is placed on the dielectric layer 252 and fills the through via 260 to form a conductive via 266, as shown in FIG. 14. The conductive material 262 may be a metal, such as Al, Cu, Ag, Au, W, etc., or a metal alloy. In some embodiments, the conductive material 262 may be a transparent metal oxide, such as indium tin oxide (ITO), indium zinc oxide (IZO), aluminum-doped zinc oxide (AZO), indium-doped cadmium oxide, etc. In some embodiments, the conductive material 262 is in direct contact with the dielectric layer 252.

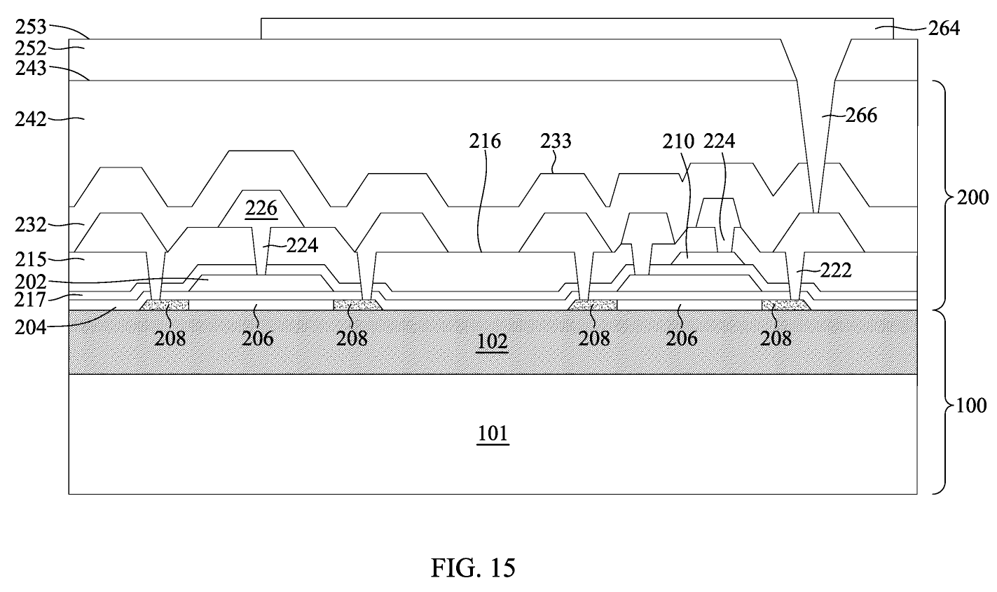

The conductive material 262 is patterned to form several electrodes 264, as shown in FIG. 15. The figure shows only one electrode. The electrode 264 is prepared to electrically connect a light emitting unit with the circuit tier. In some embodiments, the electrode 264 is designed as an anode of the light emitting unit. In some embodiments, the light emitting unit is an organic light emitting unit.

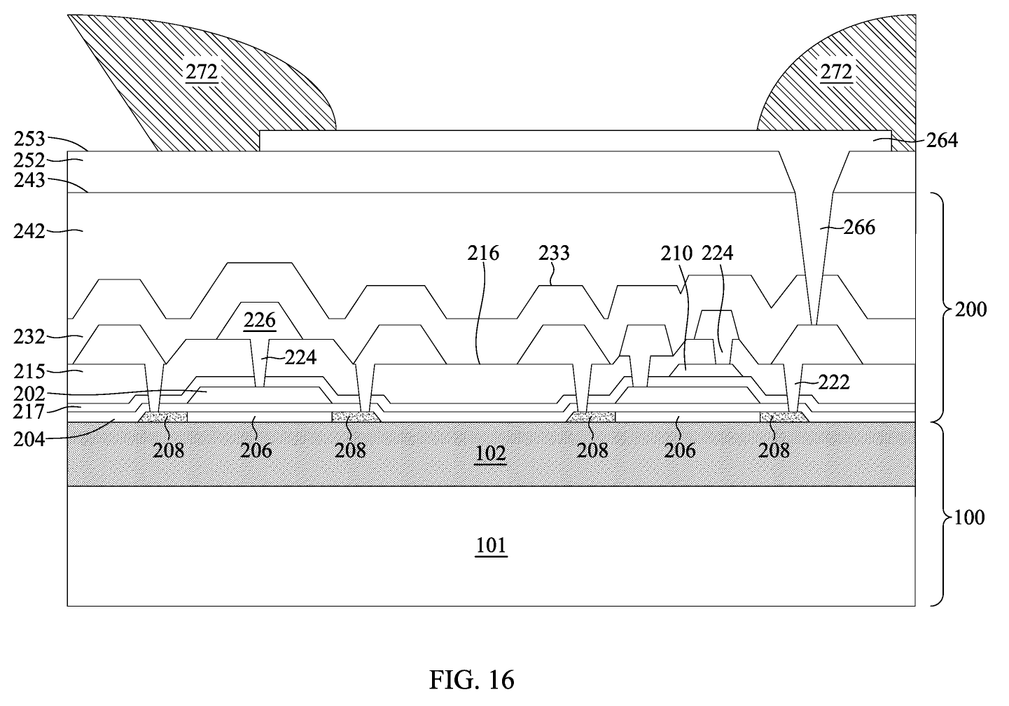

After forming the electrode 264, a spacer 272 may be optionally placed on the inorganic dielectric layer 252, as shown in FIG. 16. In some embodiments, the spacer 272 partially covers the electrode 264, leaving at least a portion of the electrode 264 open to receive light emitting material. In some embodiments, the spacer 272 comprises polymeric materials. In some embodiments, the spacer 272 comprises photosensitive materials. In some embodiments, the spacer 272 is a light-absorbing material, such as the planarization material 242. In some embodiments, the spacer 272 serves as a pattern-defining layer. In some embodiments, the patterned spacer 272 is a fluorine-free material, meaning it is substantially free of fluorine. In some embodiments, the spacer 272 is formed by photolithography.

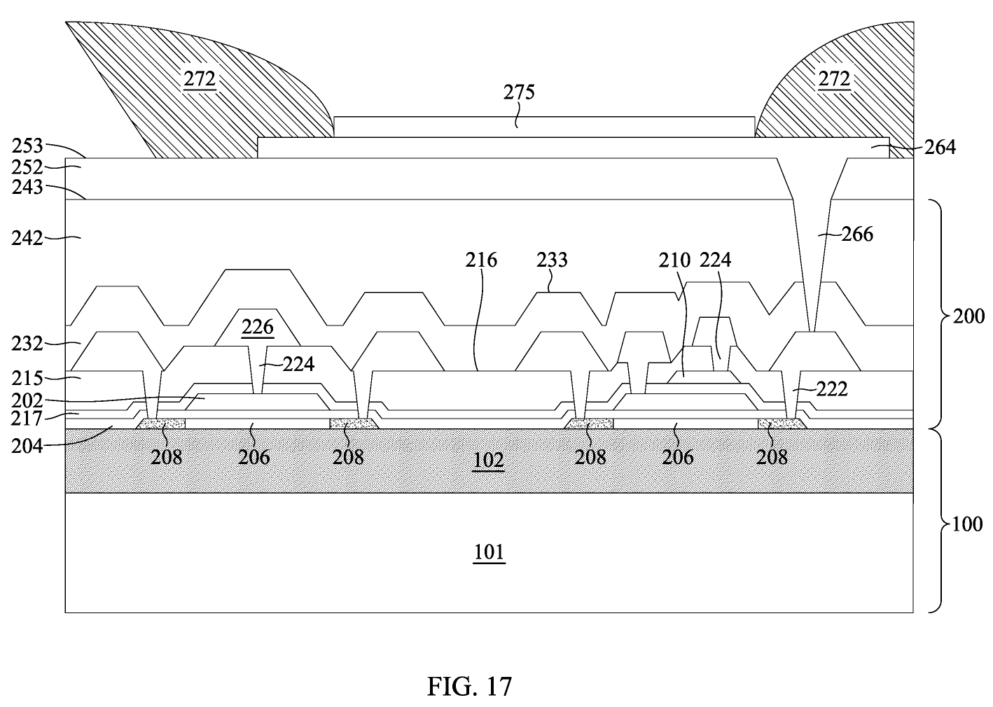

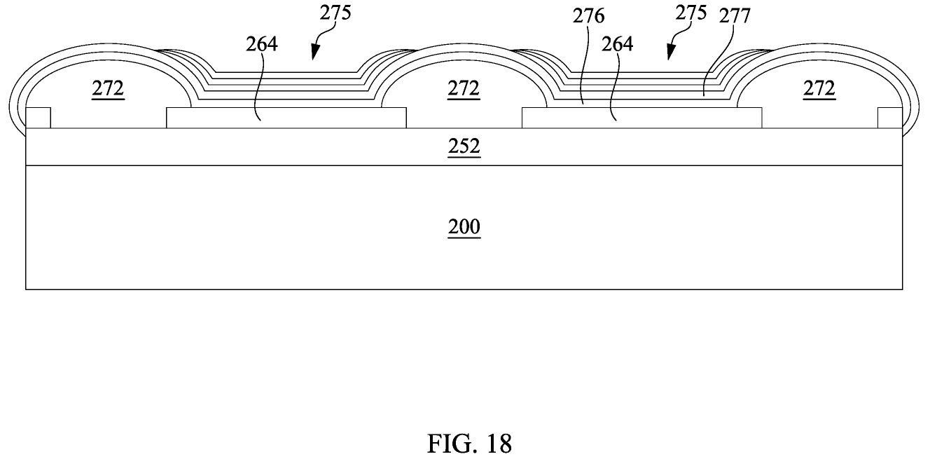

A light emitting material 275 is placed on the electrode 264, as shown in FIG. 17. In some embodiments, the light emitting material 275 comprises a first carrier injection layer, which is placed on exposed surfaces of the spacer 272 and the electrode 264. The first carrier injection layer continuously conforms to the exposed surfaces. More specifically, the exposed surface of each electrode 264 serves as the effective light emitting area of a light emitting unit. In this embodiment, all light emitting units use a shared first carrier injection layer. In some embodiments, the first carrier injection layer is used for hole injection. In some embodiments, the first carrier injection layer is used for electron injection. The first carrier injection layer 276 continuously covers multiple spacers 272 and electrodes 264, as shown in FIG. 18. As needed, the carrier injection layer 276 contacts the spacers 272. In one embodiment, the carrier injection layer 276 contacts the first electrode 215. In some embodiments, the carrier injection layer 276 is an organic layer.

The carrier transport layer 277 (or first-type carrier transport layer) is placed on the exposed surfaces of the spacers 272 and the electrode 264. The carrier injection layer 276 is placed under the first carrier transport layer 277. The carrier transport layer 277 continuously conforms to the first carrier transport layer 277. In this embodiment, all light emitting units use a shared carrier transport layer 277. In some embodiments, the carrier transport layer 277 is used for hole transport. In some embodiments, the carrier transport layer 277 is used for electron transport. The carrier transport layer 277 continuously covers multiple spacers 272 and the first electrode 264. As needed, the carrier transport layer 277 contacts the first carrier injection layer 276. In some embodiments, the carrier transport layer 277 is an organic layer.

As shown in FIG. 17 and FIG. 18, the light emitting material 275 may have multiple sublayers stacked on the electrode 264. In some embodiments, the thickness of each sublayer may be relatively smaller than the thickness of the electrode 264 or the total thickness of the circuit tier 200. In some embodiments, the thickness of a sublayer in the light emitting material 275 is at the nanometer level, while the thickness of the planarization layer 242 is at the micrometer level. Therefore, the flatness of the planarization layer 242 is crucial to the on-board performance of the light emitting material 275.

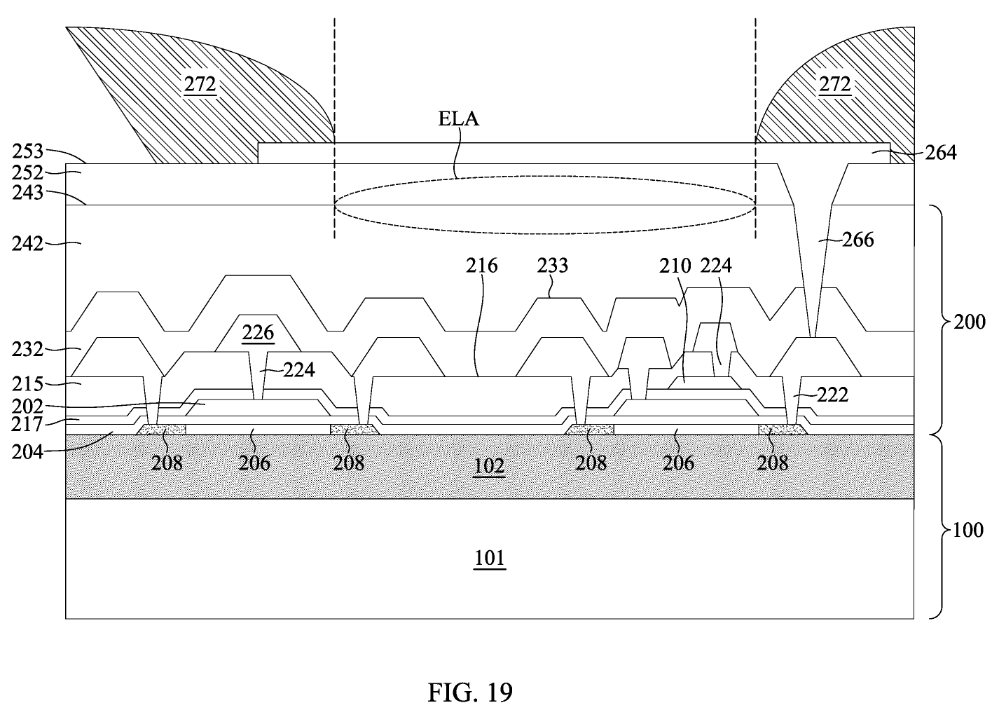

In the present disclosure, one way to define the flatness of the planarization layer 242 is to use localized flatness (LF) to define the flatness of the surface 243 of the planarization layer 242. An effective local area (ELA) on the surface 243 is defined as shown in FIG. 19. In some embodiments, the ELA is substantially equal to the area of an effective light emitting area of each light emitting unit or pixel. The effective light emitting area is the area of the electrode 264 that is not covered, i.e., the area of the electrode exposed by the spacers 272. In some cases, the ELA is vertically aligned with an effective light emitting area of the light emitting unit or pixel.

The LF in an ELA may be defined using ISO 4287, which employs a mean line system to define LF. In some embodiments, LF is represented using Rᵥ (maximum valley depth) or Rₚ (maximum peak height). In some embodiments, the |Rᵥ| or |Rₚ| of the planarization layer 242 should be controlled to be no more than about 50 times the thickness of any single layer within the light emitting material 275. For example, if the first carrier injection layer 276 is the thinnest sublayer within the light emitting material 275, then |Rᵥ| or |Rₚ| should not exceed about 50 times the thickness of the first carrier injection layer 276. If |Rᵥ| or |Rₚ| is 50 times or more the thickness of the first carrier injection layer 276, the layer may become fragile and could easily break at the largest step. The sublayer may also be a hole transport layer, light emitting layer, or electron transport layer.

A surface roughness of surface 243 differs from the roughness of the upper surface 233 of the dielectric layer 232. In some embodiments, the |Rᵥ| or |Rₚ| of the surface 243 is less than about one-third of the |Rᵥ| or |Rₚ| of the surface 233. In some embodiments, the roughness of the planarization layer 242 corresponds to the flatness of electrode 264. In some embodiments, the surface roughness of a layer or component may be represented by the arithmetic mean deviation Ra of the roughness profile as defined by JIS B 0601-2013 (i.e., the arithmetic mean of absolute values of distances from all points on the surface profile line to the mean line within a certain measurement length). The smaller the surface roughness Ra, the better the flatness of the layer or component. In some embodiments, the surface roughness Ra of electrode 264 is less than about 15nm to facilitate previous photolithography operations for forming light emitting pixels. In some embodiments, the surface roughness Ra of electrode 264 is less than about 10nm. In some embodiments, a peak-to-valley value (Rmax) of the electrode 264 is less than about 50nm to facilitate previous photolithography operations for forming light emitting pixels. In some embodiments, the peak-to-valley value (Rmax) of electrode 264 is less than about 40nm to facilitate previous photolithography operations for forming light emitting pixels.

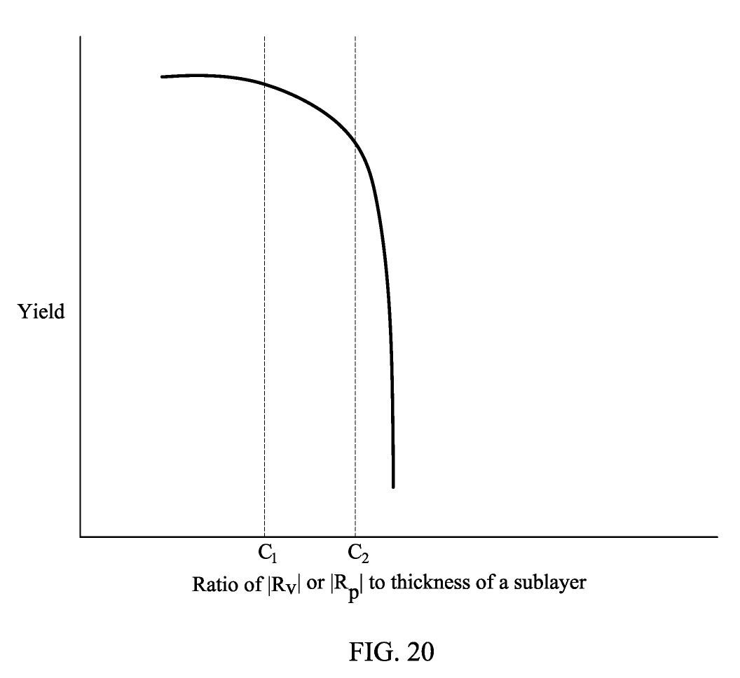

Yield is defined as a percentage of good light emitting units (or pixels) in a predetermined light emitting pixel array. As shown in FIG. 20, the Y-axis represents the yield of the light emitting pixel array, while the X-axis represents a ratio of |Rᵥ| or |Rₚ| to a thickness of a single layer. When the ratio reaches C₁, the yield is about 5% lower than the peak yield. When the ratio reaches C₂, the yield significantly decreases and is about 15% lower than the peak yield. When the ratio is greater than C₂, the yield drops sharply. In some embodiments, the peak yield is about 99% or higher.

In some cases, C₂ is about 50. In some cases, C₂ is about 60. In some cases, C₂ is about 100. In some cases, C₂ is about 150. These variations depend on the material of the sublayer. In some cases, C₁ is about 10. In some cases, C₁ is about 20. In some cases, C₁ is about 25. In some cases, C₁ is about 30.

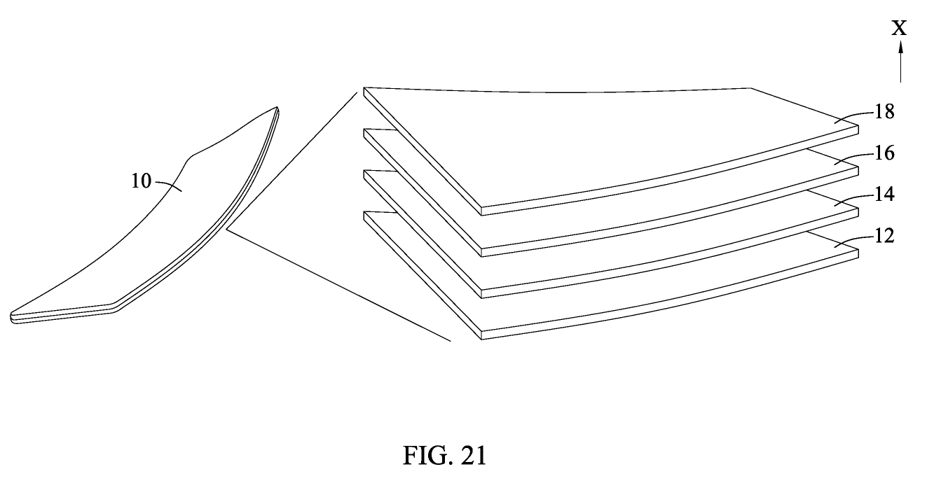

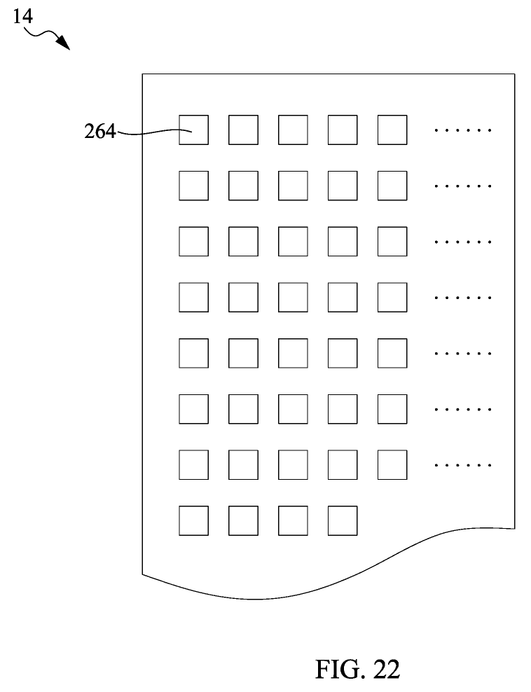

FIG. 21 illustrates a light emitting device 10, which comprises a light emitting layer 14. The light emitting layer 14 comprises the aforementioned light emitting pixel array. The light emitting pixel array may be an ultra-high pixel density array (for example, exceeding 2000ppi). The light emitting pixel array comprises an array of electrodes 264 as shown in FIG. 22.

According to the above embodiments, internal components at the circuit tier of the light emitting device, such as transistors, may be planarized (such as by CMP) to improve the surface flatness of the components, thereby enhancing the electrical performance of the transistors. In some embodiments, the buffer layer 102 of the transistor (providing the upper surface of the substrate 100) may be obtained by planarization (such as by CMP) to have a flat surface and high film thickness uniformity, thereby significantly reducing leakage current and improving the electrical performance of the transistor. In some embodiments, at least one of the active layer 205 of the transistor (including the channel 206 and the source/drain region 208), the gate dielectric layer 204, and the gate 202 is made to have a flat upper surface through a planarization process (such as by CMP), thereby improving the electrical performance of the transistor.

The features of some embodiments of the present disclosure are given in brief in the description over for a person skilled in the art to better understand various aspects of the present disclosure. A person skilled in the art would able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

What is claimed is:

1. A method of manufacturing a light emitting device, comprising:
providing a substrate;
forming a buffer material over the substrate;
performing a planarization process on the buffer material to produce a buffer layer, the buffer layer having a flat upper surface;
forming a circuit tier over the buffer layer, the circuit tier comprising a transistor, wherein forming the transistor comprises:
forming an active layer over the buffer layer;
forming a gate over the active layer; and
forming source/drain regions on portions of the active layer on opposite sides of the gate, and forming a channel below the gate and between the source/drain regions; and
forming a light emitting pixel over the circuit tier, and the light emitting pixel comprising a light emitting material.

2. The method of claim 1, wherein a chemical mechanical polishing (CMP) process is performed on the buffer material to planarize a surface of the buffer material.

3. The method of claim 2, further comprising performing a cleaning process on the buffer material after the chemical mechanical polishing process.

4. The method of claim 1, wherein forming the active layer over the buffer layer comprises:
forming an active material over the buffer layer;
performing a planarization process on the active material; and
performing a patterning process on the active material to produce the active layer.

5. The method of claim 4, wherein the planarization process comprises a chemical mechanical polishing process, and the method further comprises performing a cleaning process on the active material after the chemical mechanical polishing process.

6. The method of claim 1, wherein forming the gate over the active layer comprises:
forming a gate material layer over the active layer;
performing a planarization process on the gate material layer; and
performing a patterning process on the gate material layer to produce the gate.

7. The method of claim 6, wherein the planarization process comprises a chemical mechanical polishing process, and the method further comprises performing a cleaning process on the gate material layer after the chemical mechanical polishing process.

8. A method of manufacturing a light emitting device, comprising:
forming a circuit tier on a substrate, the circuit tier comprising a transistor, wherein the substrate comprises a base material and a buffer layer over the base material, and forming the transistor comprises:
forming an active layer over the buffer layer;
forming a gate over the active layer; and
forming source/drain regions on portions of the active layer on opposite sides of the gate, and forming a channel between the source/drain regions,
wherein the active layer is produced with a flat upper surface through a planarization process; and
forming a light emitting pixel over the circuit tier, and the light emitting pixel comprising a light emitting material.

9. The method of claim 8, wherein the buffer layer provides an upper surface of the substrate, and the method further comprises performing a chemical mechanical polishing (CMP) process on the buffer layer to planarize the upper surface of the substrate.

10. The method of claim 8, wherein the active layer is produced with a flat upper surface through a chemical mechanical polishing (CMP) process.

11. The method of claim 8, further comprising performing a chemical mechanical polishing (CMP) process on the gate to have a flat upper surface.

12. The method of claim 8, wherein a gate dielectric layer is further comprised between the channel and the gate, and the method further comprises performing a planarization process on the gate dielectric material to form the gate dielectric layer.

13. A light emitting device, comprising:
a substrate comprising a base material and a buffer layer over the base material;
a circuit tier on the substrate, the circuit tier comprising a transistor, the transistor comprising:
an active layer over the buffer layer;
a gate over the active layer; and
source/drain regions located at the active layer and on opposite sides of the gate, with a channel below the gate and between the source/drain regions,
wherein the buffer layer comprises a planarized upper surface, and the planarized upper surface has a surface roughness Ra of less than at least 5nm; and
a light emitting pixel over the circuit tier, and the light emitting pixel comprising a light emitting material.

14. The light emitting device of claim 13, wherein the planarized upper surface of the buffer layer has a surface roughness Ra of less than at least 0.1nm.

15. The light emitting device of claim 13, wherein the buffer layer provides an upper surface of the substrate, the substrate comprises a locally flat area with a surface roughness of less than at least 5nm, and the locally flat area has a surface uniformity with a variation from the surface roughness of less than 15%, wherein the channel and the source/drain regions are in the locally flat area, and the gate is on the locally flat area.

16. The light emitting device of claim 13, wherein the active layer comprises a planarized upper surface and a surface roughness Ra of less than at least 5nm.

17. The light emitting device of claim 16, wherein the upper surface of the active layer comprises an upper surface of the channel and an upper surface of the source/drain regions.

18. The light emitting device of claim 16, wherein, in a cross-sectional view of the transistor, the active layer has a uniform thickness and a surface roughness Ra of less than at least 0.1nm.

19. The light emitting device of claim 13, wherein the gate comprises a planarized upper surface and a surface roughness Ra of less than at least 5nm.

20. The light emitting device of claim 19, wherein, in a cross-sectional view of the transistor, the gate has a uniform thickness and a surface roughness Ra of less than at least 0.1nm.
